(19) United States
(12) Patent Application Publication
(10) Pub. No.: US 2009/0040878 A1
(43) Pub. Date: Feb. 12, 2009

(54) Invitation card with built-in countdown feature

(76) Inventors: Joseph Domes, Huntington, NY (US); John Mizzi, Poughkeepsie, NY (US)

Correspondence Address: ALFRED M. WALKER, 225 OLD COUNTRY ROAD, MELVILLE, NY, 11747-2712, US

(21) Appl. No.: 11/891,614

(22) Filed: Aug. 10, 2007

(51) Int. Cl. G04F 10/00; G09F 1/00; H03K 19/173

(52) U.S. Cl. 368/107; 326/37; 40/124.01; 40/124.02; 40/124.03; 40/124.04

(57) ABSTRACT

A tangible invitation card extends an invitation by displaying information with regard to the invitation. A settable real-time clock sets a predetermined time which is displayed on a screen on the invitation card of time remaining to a selected target date for an event or earlier RSVP date related thereto. The card is programmed such that as the target date is approached, one or more visual displays and/or sounds count down and announce the time left to the target date for the RSVP or event. The invitation card is programmed with the necessary information to enable it to perform its reminder mission.

### FIELD OF THE INVENTION

The present invention relates to an invitation cards with built-in electronic audio/visual countdown features.

### BACKGROUND OF THE INVENTION

Event reminders vary from the proverbial “string around a finger” to computer calendars with audio-visual cues designed to get our attention as an event approaches. The stand-alone timer of Yeh in patent application US 2006/0087920 not only has a real-time clock, but an audio-visual reminding device. Patent application US 2003/0136036 of Zubil combines a real-time digital clock with a foldable card holder for display of a business card. Greeting cards with audio or flashing lights are commonly available. Two examples of prior art relating to this genre are U.S. Pat. No. 5,036,698 of Johnson which describes a classic greeting card with a sound recording, and the animated device of Wilson (U.S. Pat. No. 4,299,041) which relates to greeting cards with both audio and visual features involving flashing light emitting diodes (LED's). However, the prior art does not reveal an invitation card with a built-in countdown feature.

### OBJECTS OF THE INVENTION

It is therefore an object of the present invention to provide a card stock invitation which includes built-in electronic audio/visual countdown features.

It is also an object of the present invention to provide a card stock invitation which utilizes audio/visual stimuli to periodically remind an invitee of an upcoming event.

Other objects will become apparent from the following description of the present invention.

### SUMMARY OF THE INVENTION

In keeping with these objects and others which may become apparent, the present invention is a tangible physical paper or cardstock invitation card announcing a specific event that also has the ability to remind the recipient of the approaching date by audio and visual means, specifically a daily countdown. The method and system of this invention includes means for programming the invitation card with the necessary information to enable it to perform its reminder mission.

Since the target market for these invitation cards is traditional customers who value the sending of physical cards (as opposed to computer screen-transmitted “E-cards”) by standard mail, the programming effort is designed to be simple, not requiring expert computer skills. Also, since an event such as a wedding often involves sending many invitations, the cost of each card and the time involved in programming each card should be held to a minimum.

Three different methods of programming the cards are illustrated. The most costly and time-consuming involves each card equipped with a programmer subsystem detachably attached to the card itself as a fold-out companion. It has a user interface panel and requires, at minimum, the entry of the present date and time as well as the date of the event. If a recorded voice feature is included, a recorded message would also have to be spoken into the programmer. In some cases, a countdown to an “RSVP date” (i.e. response date, as in “Repondez, S'il Vous Plait” in French language, or “Respond, if you please” in English language) is also desired; this date would also have to be entered. While this method is feasible if cost is not much of a factor and the number of invitations is small, it is desirable to program the cards during an engraving or printing process, or to have the customer or store clerk program an entire batch simultaneously.

If engraved or printed cards are ordered, the programming can be accomplished during the printing process as each card is printed or engraved, or one of the batch programming methods to be described can be used after the run of cards is printed or engraved. In this manner, the customer is not involved in the programming. Cards can be ordered by phone or over the internet and then delivered to the customer. If a voice-entry feature is included, the customer can call the engraver/printer to enter this item remotely.

If cards are not printed, the customer would write-in the pertinent information. The customer or a store clerk would also be programming the cards. Even if the cards are printed, they may not be pre-programmed during the process. A physical store can be equipped with an in-store programming station. The cards would be placed into the station and then a clerk or the customer would proceed to program all of them simultaneously. In a similar embodiment, the lid of a box of cards can include a batch programmer with a user interface panel on the top surface. This would program all cards in the box simultaneously much as in the programming station.

Although a wide variety of audio/visual features can be implemented, in the preferred embodiment, the card would be a flat invitation card (as opposed to a folded card) with very flat electronics and battery built-in. At least one shielded magnet or double-sided stick surface for attachment to a magnetic or other surface such as a refrigerator would be attached to the back surface. The electronics will include a microcomputer with factory loaded countdown software, a real-time clock function, at least one liquid crystal display (LCD) to display the countdown number, audio playback, and one or more LED's. Display technology in current test-markets include flexible “electronic ink” LCD type displays as well as organic LED's. These can be substituted as they become available. Obviously, animated displays using cartoon characters or changing color designs can be incorporated. The audio can be all factory supplied, or custom messages in a person's voice can be added. The computer calculates the time left before the RSPV and event days and displays the appropriate “DAYS LEFT” as a countdown. The reminder cues are factory programmed and get more urgent and intrusive as the event day approaches.

All programmer devices use the same design of user interface panel in the preferred embodiment. The panel includes a column of prompting LED's leading the user to enter the pertinent information in the proper format and order. A numeric keypad is used to enter information. Command keys are used to communicate with the programmer. Numeric LCD's are used to display date and time along with RSPV/EVENT and AM/PM designation dots.

In the attached programmer instance, a perforated seam separates each invitation card of this invention from its adjacent programmer to which it is electrically attached. In this case, it is possible to share a single micro computer physically in the card portion to also perform programmer functions. After programming, the programmer card is detached from the invitation card, and the electrical connection is simultaneously severed. The programmer portion with the user interface panel is then discarded.

Two types of batch programmers are described whether implemented as in-store programming stations or as card box-top programmers. The first type is physically connected to each card via a cable from the programmer making conductive contact with each card via contacts attached to an edge of each invitation card which would make contact with conductive rails inside the programming station or card box. In the preferred embodiment, an inductive coupling or a radio frequency link as used in RFID tags is used to transfer data from programmer to each card simultaneously. This involves the use of printed conductive loops or primitive flat antennas. The RFID technology is well proven and quite inexpensive.

### BRIEF DESCRIPTION OF THE DRAWINGS

The present invention can best be understood in connection with the accompanying drawings. It is noted that the invention is not limited to the precise embodiments shown in drawings, in which:

FIG. 1 is a front view of an invitation card with countdown reminder of this invention;

FIG. 2 is a chart showing the programming methods available to a customer as a function of the purchase method and type of card;

FIG. 3 is a front view of the user interface panel of a programmer;

FIG. 4 is a front view schematic representation of an invitation card attached to an individual programmer card;

FIG. 5 is a perspective view of a card box with a programmer attached to its lid;

FIG. 6 is a block diagram of a batch programmer electrically attached to a batch of invitation cards;

FIG. 7 is a block diagram of a batch programmer attached to a batch of invitation cards using RFID type inductive or radio frequency coupling;

FIG. 8 is a block diagram of the internal hardware of a programmer and an invitation card using RFID-type communications;

FIG. 9 is a high level flow chart of software within an invitation card;

FIG. 10 is a high level flow chart of software for TNC[I] representing a “6 DAY” to event countdown, and

FIG. 11 is a high level flow chart of software for TNC[I+6] representing a “0 DAY” to event countdown.

### DETAILED DESCRIPTION OF THE INVENTION

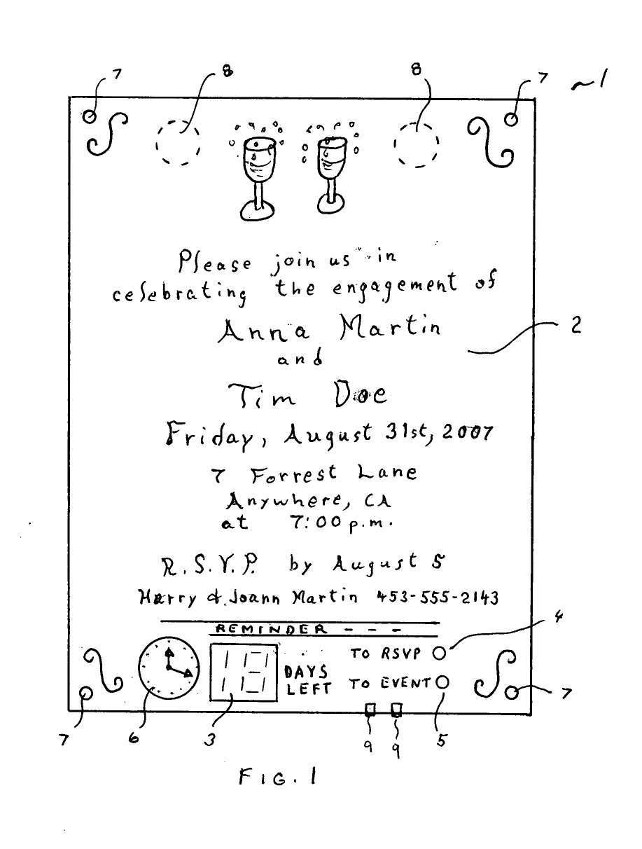

FIG. 1 shows tangible invitation card 1 of this invention with text information 2 and countdown display 3, such as an LCD 3, which is used to display the number of days left. It is also possible to count down days and hours if desired, but this option was not selected for the preferred embodiment. Tangible invitation card 1 is a physical card, made up of paper, cardstock or other suitable printing material. Visual stimuli reminders such as LCD dots 4 and 5 differentiate between DAYS LEFT for “RSVP” date (i.e. response date, for example, as in “Repondez, s'il vous plait” in French language, or “Respond, if you please” in English language) for the event itself. A clock 6, such as an LCD analog clock face 6, with current time can be optionally implemented. Other optional visual stimuli, such as, for example, LED's 7 at each corner of the tangible invitation will participate as the countdown progresses. Preferably, tangible invitation card 1 includes fasteners, such as flat shielded magnets 8 which are attached to the back side of tangible invitation card 1 to facilitate attachment to a display surface such as a magnetic surface, such as a refrigerator door. Fasteners can also be double sided sticky tape with peel-off layers. Electrical contacts 9 are optionally included to facilitate batch programming of card 1 if contact type attachment to a programmer is used. Audio reminders in the form of sounds from one or more loudspeakers 58 can also be provided. These sounds can announce the upcoming date, or optionally can provide music or a tape recorded announcement from the event honoree, such as a bride saying “We'd love to have you attend our special wedding.”

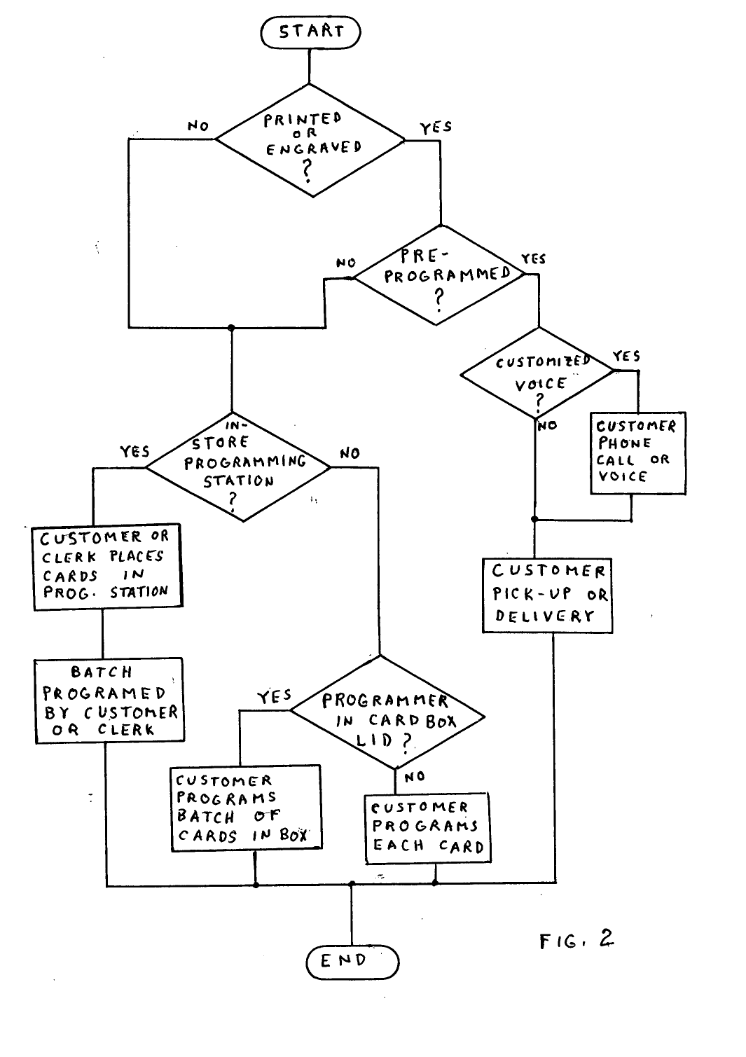

FIG. 2 shows purchase and programming choices available to a customer. If the tangible invitation cards 1 are printed or engraved, they can be pre-programmed during the printing/programming process or immediately afterwards and picked-up or delivered to the customer. If there is the option of a custom message in the customer's voice, a phone call or visit by the customer is required if the tangible invitation cards 1 are to be pre-programmed. If the tangible invitation cards 1 are not pre-programmed, an in-store programming station may be available so that a customer or clerk can batch program the tangible invitation cards 1. Alternatively, a similar programmer can be available as attached to the lid of a box of tangible invitation cards 1. In this way, the customer can program a box of tangible invitation cards 1 at a time. Finally, if each tangible invitation card 1 is purchased with an attached programmer panel, each tangible invitation card 1 will be programmed individually.

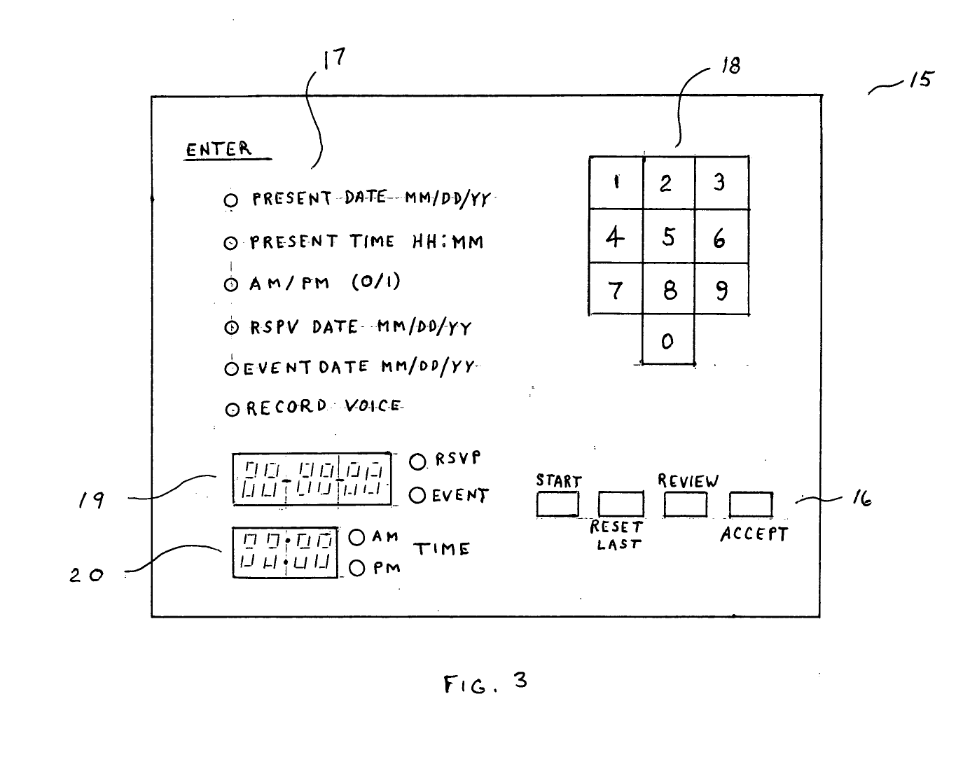

The user interface panel 15 on the front of a programmer card is shown in FIG. 3. The process is started by pressing the start button among command buttons 16; other buttons are self-explanatory. Then a series of prompting stimuli, such as, for example, LED's 17 will light one at a time guiding the user in entering pertinent information by using an input device, such as a numeric keypad 18, a touch screen or other input stylus. Numeric audio/visual stimuli, such as a loudspeaker or an LCD 19, is used to display the target date for either RSVP or Event date as indicated by adjacent stimuli, such as, LCD dots. Numeric stimuli, such as LCD 20, displays digital or analog time of day. A reset button can be provided for the guest to use to stop the stimuli display for a later announcement.

An example of a typical programmer card, such as programmer card 25 attached to an individual tangible invitation card 1, is shown in FIG. 4. After use it is preferably detached, such as by tearing at perforated seam 28, and discarded.

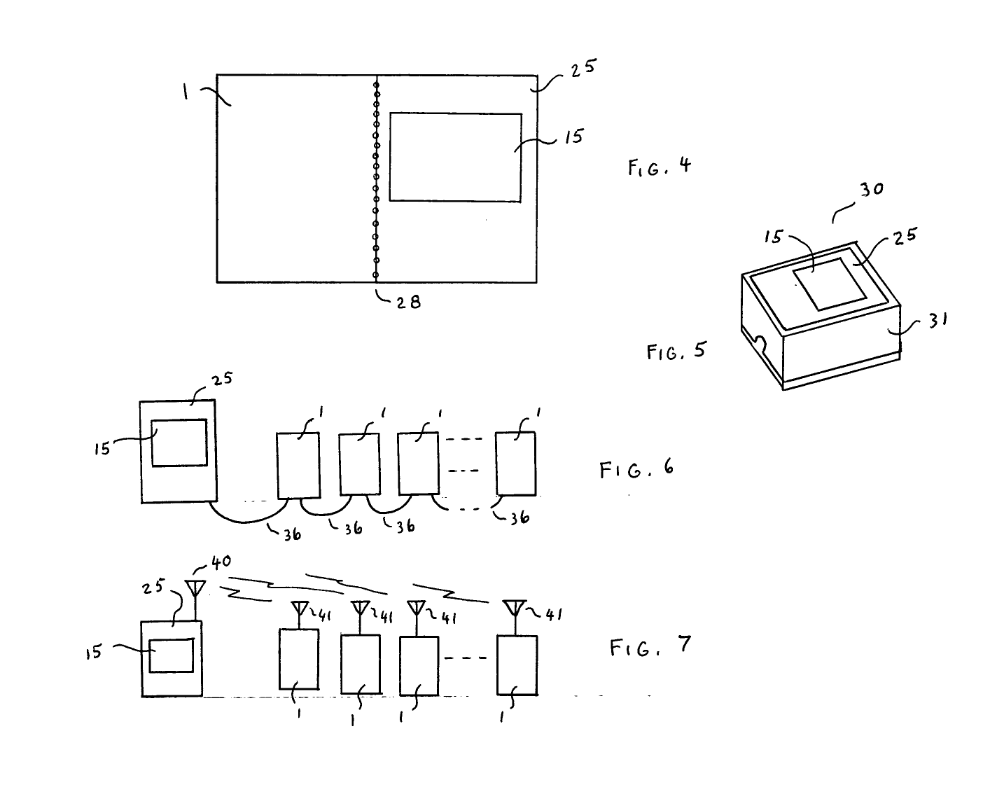

FIG. 5 shows a card box 30 with programmer 25 attached to the lid 31.

A conductive attachment 36 from programmer 25 to each tangible invitation card 1 is shown in FIG. 6.

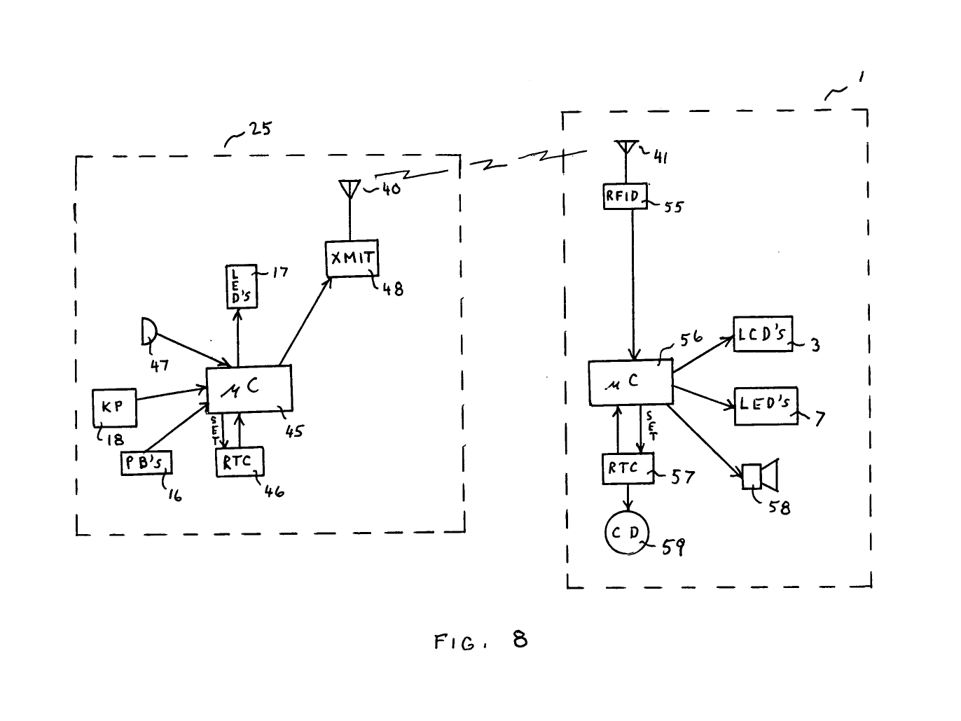

An option for a radio frequency identification tag, such as, for example, an RFID type of communications link using antenna 40 on programmer 25 linking to each tangible invitation card 1 via card antenna 41, is shown in FIG. 7.

The block diagram of FIG. 8 shows programmer 25 communicating with a tangible invitation card 1 via optional RFID type link. Programmer 25 includes a flat card with interface panel 15 attached on its front side. It contains microcomputer 45 which can be one of many inexpensive chips available such as, for example, a PIC16F84A-20P. It is attached to real-time clock chip 46 although this function can be software implemented using computer 45. Commands, such as push buttons 16 and keypad 18 provide input from panel 15. Prompt stimuli, such as LED's 17 on panel 15, are lighted as appropriate by computer 45. An optional microphone 47 is used to input voice or other sound messages. The output data stream is then fed to transmitter 48 through antenna 40 for reception by optional RFID-type receiver 55 through antenna 41 both housed in a tangible invitation card 1. Microcomputer 56 can be any of a number of small inexpensive chips such as a PIC12F675. Real time clock 57 can optionally drive an analog display, such as, for example, an LCD analog type clock face display 59. Audio/visual output, such as loudspeaker 58, countdown LCD 7 and LED's 3 are all driven by computer 56 under software control.

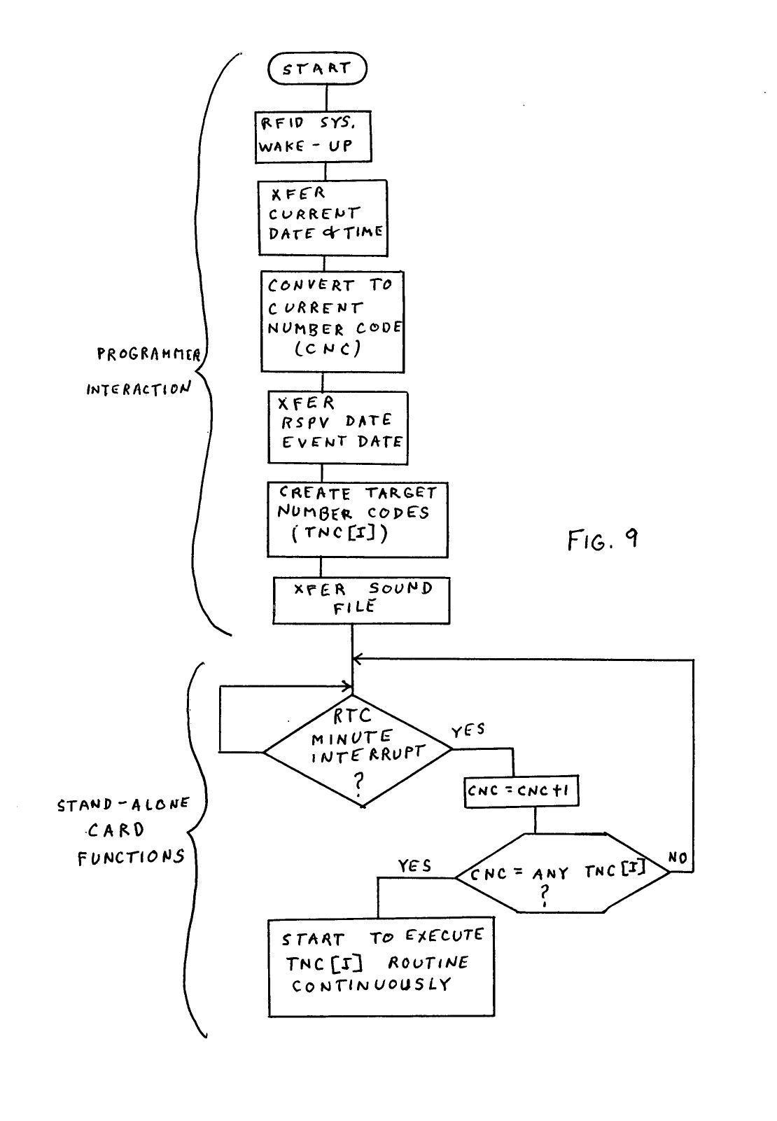

A flow chart of resident software in a typical tangible invitation card 1 is shown in FIG. 9. The example of FIG. 9 shows top portion involves interaction during programming, while the bottom portion relates to stand-alone card function as time is being counted down. The RFID receiver causes system wake-up, then the current date and time is transferred and converted into an internal current number code (CNC). Then the RSVP date (if used) and the event date are transferred and internally a list of target number codes (TNC's) is created for each of the countdown days. The voice file (if any) is also transferred. Each elapsing minute increments the CNC. The CNC is then compared to the TNC list; if there is a match, the current TNC routine is interrupted and the matched TNC[I] routine is initiated and run continuously until interrupted. As the countdown progresses, 10 . . . 9 . . . 8 . . . etc., the TNC routine gets more aggressive (louder, flashier, and/or more intrusive) as the target date is approached.

Although the recipient demographic includes many individuals with limited or no computer skills, some limited user selected options can be incorporated into invitation card 1. One option that would be appropriate is analogous to the “snooze alarm” feature of an alarm clock. Here, the option would be used to interrupt the audio/visual or just the audio portion of the reminder routine for a fixed period (such as an hour or a day) upon the recipient pressing a “panic” button implemented at the factory for this purpose and indicated on the card front surface. Referring to the flow chart of FIG. 9, this option is introduced into the software flow by inserting a “panic” interrupt decision block atop the “RTC minute interrupt” block. The action that interrupts the audio/visual or just the audio “reminder antics” would follow the “yes” result and would automatically time out after the factory-selected period has elapsed restoring full “reminder” functions.

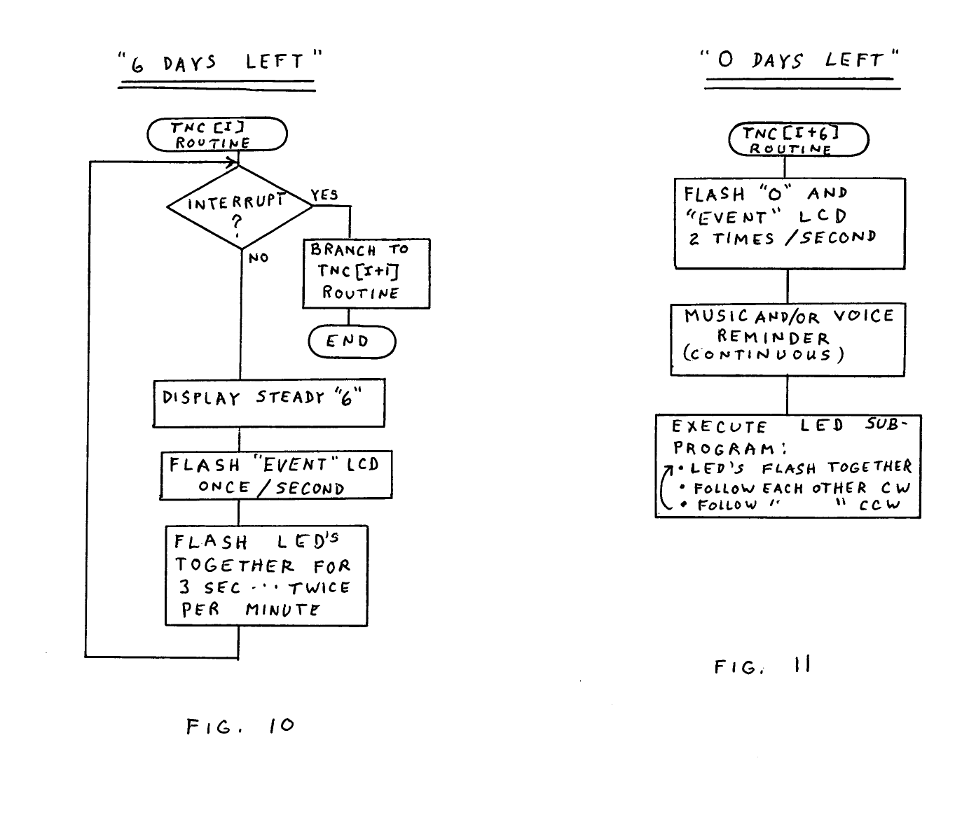

FIG. 10 illustrates a typical example in use, showing a “mild” routine counting down “6 DAYS LEFT”. Note that a steady “6” is displayed along with Event LCD once/second. Stimuli, such as LED's flash together for a pre-programmed time, such as, for example, 3 seconds only twice per minute.

FIG. 11 shows a typical output of an aggressive “0 DAYS LEFT” routine with “0” and Event flashing twice/second, music and voice at full volume, LED sub-program flashes LED's 3 times per second, first together, then clockwise, then counterclockwise . . . etc. This is just an illustration of many optional displays and stimuli as to what can be programmed at the factory.

In the foregoing description, certain terms and visual depictions are used to illustrate the preferred embodiment. However, no unnecessary limitations are to be construed by the terms used or illustrations depicted, beyond what is shown in the prior art, since the terms and illustrations are exemplary only, and are not meant to limit the scope of the present invention.

It is further known that other modifications may be made to the present invention, without departing the scope of the invention, as noted in the appended Claims.

1. Apparatus for extending an invitation comprising:
a tangible card member displaying information with regard to said invitation, said card member including
a microcomputer;
a seizable real-time clock
a screen displaying time remaining to a selected target date for an RSVP or event; and
indicator means controlled by said microcomputer for indicating the time left to the target date for the RSVP or event as the target date approaches.

2. The apparatus of claim 1 in which said card member includes electrical contacts on said card member to enable said microcomputer to receive programming instructions.

3. The apparatus of claim 1 wherein said card member includes electrical contacts on said card member to enable said microcomputer to receive programming instructions, wherein further said electrical contacts are connected to a programmer card having command buttons to program said microcomputer.

4. The apparatus of claim 3 in which said card member is in a container with other card members, and said programmer card is attached to said box for programming all of said card members simultaneously, all of said card members being in electrical contact with said programmer card.

5. The apparatus of claim 3 in which said programming card is removably attached to said card member, said programming card being detached from said card member after said microcomputer is programmed and ready to be delivered to an invitee.

6. The apparatus of claim 1 in which said programming means includes an RFID receiver for receiving programming instructions.

7. The apparatus of claim 6 having a programmer card having command buttons to program said card member and an RFID transmitter to transmit instructions selected by said command buttons to said card member.

8. The apparatus of claim 7 in which said card member is in a container with other card members, and said programmer card is attached to said box for programming all of said card members simultaneously, all of said card members being in RFID communication with said programmer card.

9. The apparatus of claim 1 wherein said microcomputer is programmed such that as said target date approaches, said at least one visual display and/or sound count down and announce the time left to the target date for the RSVP or event in a plurality of announcements.

10. The apparatus of claim 9 wherein said microcomputer is programmed such that as said target date approaches, said plurality of announcements as the event date approaches are presented at increasing frequency of time.

11. The apparatus of claim 9 wherein said microcomputer is programmed such that as said target date approaches, said plurality of announcements as the event date approaches are presented at increasing intrusive intensity.

12. A method of producing a tangible invitation comprising the steps of:
forming a tangible card member containing information with regard to said invitation and a screen for real time display of counting down to either or both of a target date for an RSVP or event;
providing a settable real-time clock;, and
programming said card member for entry of present time real time display to either or both the target date for the RSVP or event

13. The method of claim 12 in which a programmer card is employed to program said card member.

14. The method of claim 13 in which said programmer card is electrically connected to said card member.

15. The method of claim 13 in which said programmer card delivers instructions to said card member using an RFID) transmitter.

16. The method of claim 13 in which a plurality of card members are programmed together.

17. The method of claim 16 in which said card members are in a box, said card members are contacted together and to said box, said box having program buttons to delivering program instructions to said card members.

18. The method of claim 16 in which each of said card members has an RFID receiver, said box having an RFID transmitter and program buttons to deliver program instructions wirelessly to said card members.

19. Apparatus for extending an invitation comprising:
a tangible card member displaying information with regard to said invitation;
a settable real-time clock;
a screen displaying time remaining to selected RSVP or event; and
means for programming said card member such that as the target date is approached, at least one visual display and/or sound counts down and announces the time left to the target date for the RSVP or event;
said programming means including electrical contacts on said card member to receive programming instructions, said electrical contacts being connected to a programmer card having command buttons to program said card member with the required present time and target dates for the RSVP or event;
wherein as said target date approaches, said at least one visual display and/or sound count down and announce the time left to the target date for the RSVP or event in a plurality of announcements.

20. The apparatus of claim 19 wherein as said target date approaches, said plurality of announcements, as the event date approaches are presented at increasing frequency of time.

21. The apparatus of claim 19 wherein as said target date approaches, said plurality of announcements as the event date approaches are presented at increasing intrusive intensity.

22. Apparatus for extending an invitation comprising:
a tangible invitation card, said card having a countdown display displaying a predetermined countdown of time until an event;
said tangible invitation card being a physical card, made up of paper or cardstock printing material;
said countdown display of said tangible invitation card having perceptible reminder stimuli displaying a countdown time until an event
said tangible card having a settable real time clock revealing time left as said countdown progresses.

23. The apparatus as in claim 22 further comprising a fastener for attaching said tangible invitation card to a viewable surface.

24. The apparatus as in claim 23 wherein said fastener is a magnet.

25. The apparatus as in claim 22 wherein said stimuli is an LED visual display.

26. The apparatus as in claim 22 wherein said stimuli is a sound loudspeaker.

27. The apparatus as in claim 22 further comprising a user-operable reset button to interrupt an announcement and allow a later subsequent announcement.
